(19) United States
(12) Patent Application Publication
(10) Pub. No.: US 2014/0028164 A1
(43) Pub. Date: Jan. 30, 2014

(54) ELECTRONIC DEVICE ENCLOSURE

(71) Applicants: YUN-LUNG CHEN, Tu-Cheng (TW); CHUNG CHAI, Tu-Cheng (TW); ZHI-QIANG LI, Wuhan City (CN); LEI ZHOU, Wuhan City (CN)

(72) Inventors: YUN-LUNG CHEN, Tu-Cheng (TW); CHUNG CHAI, Tu-Cheng (TW); ZHI-QIANG LI, Wuhan City (CN); LEI ZHOU, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/584,756

(22) Filed: Aug. 13, 2012

(30) Foreign Application Priority Data
Jul. 30, 2012 (CN) 2012102665462

(51) Int. Cl. H05K 5/03

(52) U.S. Cl. 312/223.2

(57) ABSTRACT

An electronic device enclosure includes a base, a side plate attached to the base, and a rotating member rotatably attached to the side plate. The base includes a rear wall and a sidewall connected to the rear wall. The rear wall includes a rear wall flange, and a clipping hole is defined in the sidewall. The side plate includes a clamping portion. The rotating member includes a blocking portion. The side plate is moveable in a first direction substantially perpendicular to the rear wall to engage the clamping portion in the clipping hole, and the blocking portion engages with the rear wall flange to prevent the side plate moving in a second direction substantially opposite to the first direction.

### BACKGROUND

1. Technical Field

The present disclosure relates to enclosures, and more particularly to an electronic device enclosure for securing a side plate to a rear plate.

2. Description of Related Art

An electronic device enclosure, such as a personal computer case, may include a base and a side plate secured to the base with a plurality of screws. Using screws is very laborious and time-consuming. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device enclosure in accordance with an embodiment.

FIG. 2 is an exploded, isometric view of a side plate, a securing member and a rotating member of FIG. 1.

FIG. 3 is an assembled view of the items in FIG. 2, and showing the side plate in a lock position.

FIG. 4 is an assembled view of the electronic device enclosure of FIG. 1.

FIG. 5 is an enlarged view of circle V of FIG. 4.

FIG. 6 is an assembled view of the electronic device enclosure of FIG. 1.

FIG. 7 is similar to FIG. 2, but showing the side plate in an unlock position.

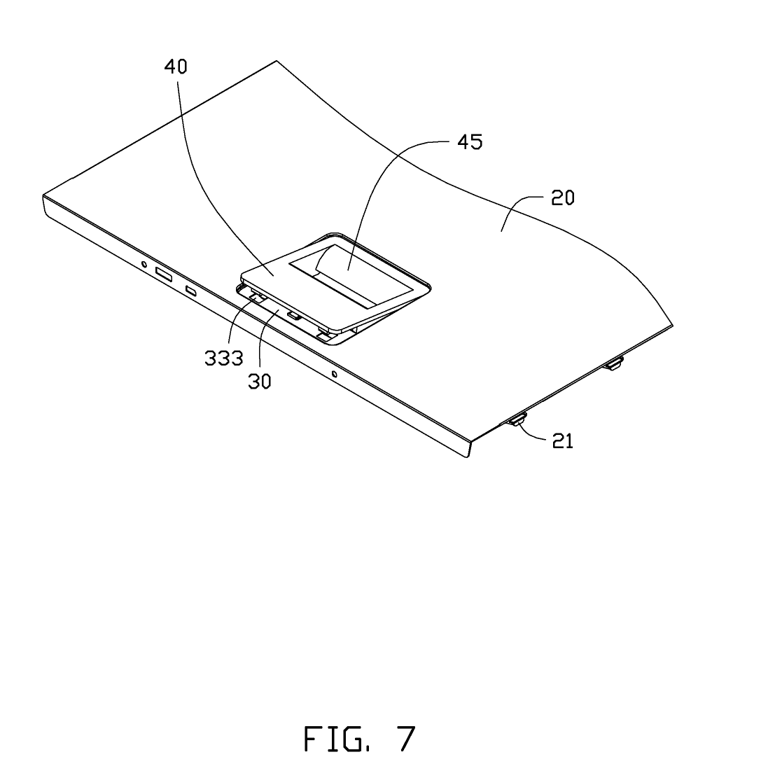

FIG. 8 is similar to FIG. 8, but viewed from a different aspect.

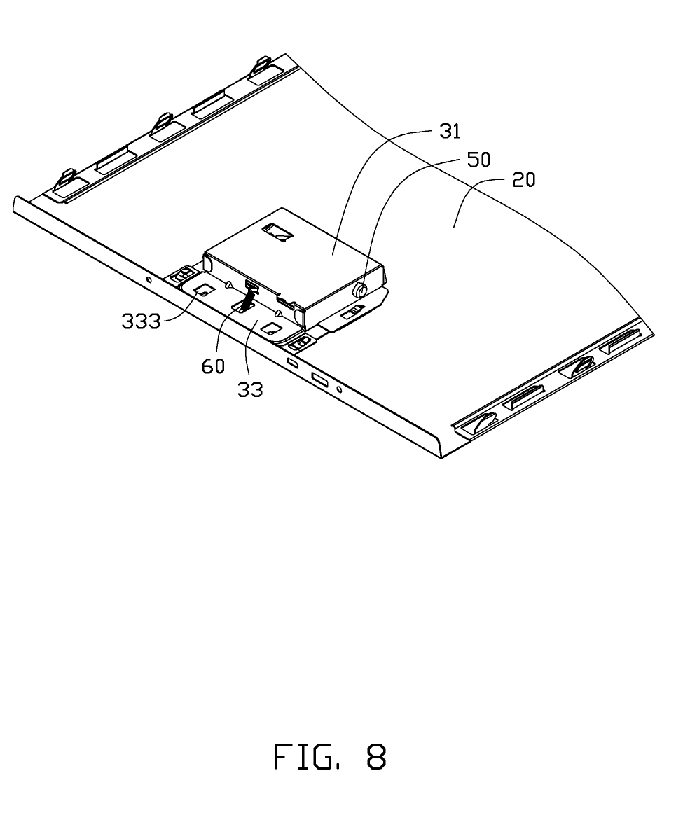

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

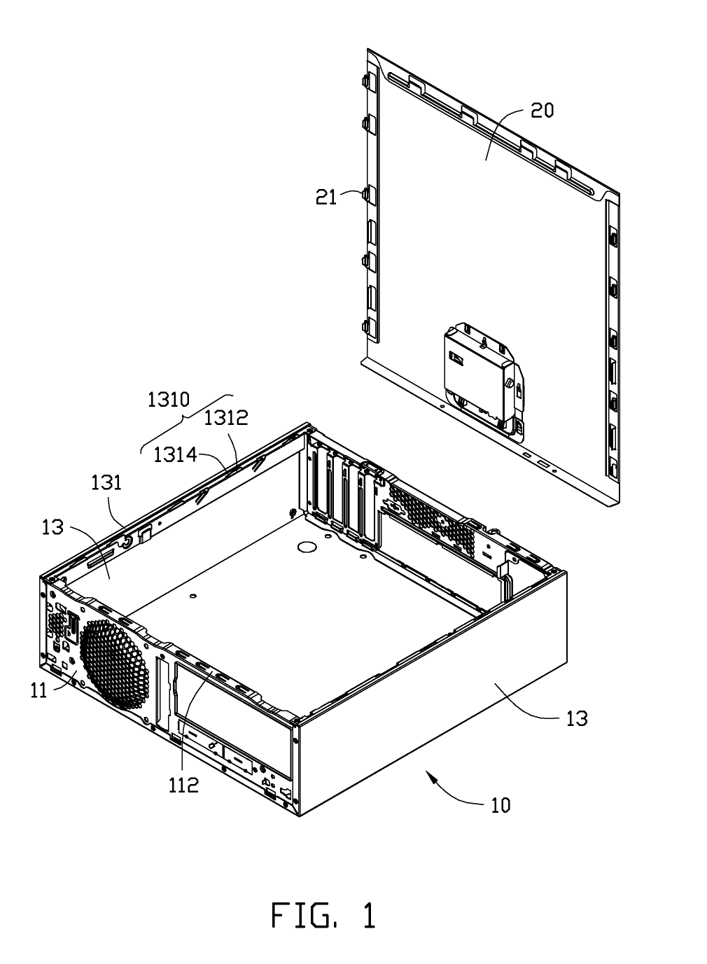

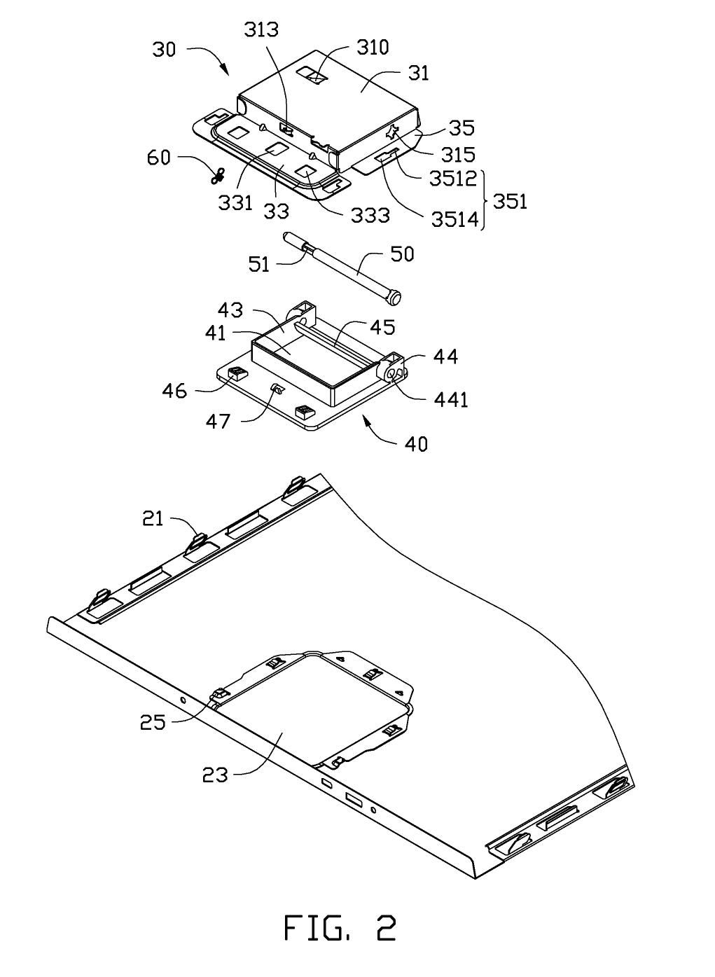

FIGS. 1-2 illustrate an electronic device enclosure in accordance with an embodiment. The electronic device enclosure includes a base 10, a side plate 20 attached to the base 10, a securing member 30 attached to the side plate 20, and a rotating member 40 rotatably attached to the securing member 30. In one embodiment, the electronic device enclosure is a personal computer chassis or a server chassis.

The base 10 includes a rear wall 11 and two sidewalls 13 extending from opposite sides of the rear wall 11. In one embodiment, each of the two sidewalls 13 is substantially perpendicular to the rear wall 11. A rear wall flange 112 extends from the rear wall 11. A sidewall flange 131 extends from each of the two sidewalls 13. A plurality of clipping holes 1310 are defined in the sidewall flange 131. Each of the plurality of clipping holes 1310 includes a guiding portion 1312 and a positioning portion 1314 communicating with the guiding portion 1312. In one embodiment, a width of the guiding portion 1312 is larger than a width of the positioning portion 1314.

A plurality of clamping portions 21 extends from opposite edges of the side plate 20, corresponding to the plurality of clipping holes 1310. A hole 23 is defined in the side plate 20, and a plurality of inserting portions 25 are located on the side plate 20 and surround the hole 23.

The securing member 30 includes a box 31 and a securing panel 33 extending from an edge of the box 31. A plurality of extending flanges 35 extends from the box 31 and the securing panel 33. Sliding slots 351 are defined in the plurality of extending flanges 35, corresponding to the plurality of inserting portions 25. Each of the plurality of sliding slots 351 includes a small portion 3512 and a large portion 3514, communicating with the small portion 3512. In one embodiment, a width of the small portion 3512 is less than a width of the large portion 3514. An engaging portion 310 is located on a bottom portion of the box 31, and a first hook 313 is located on a side panel of the box 31, adjacent to the securing panel 33. A first pivoting hole 315 is defined in each of opposite side panels of the box 31. A first through hole 331 and two second through holes 333 are defined in the securing panel 33, and the two second through holes 333 are located on opposite sides of the first through hole 331.

The rotating member 40 defines an opening 41, and a receiving portion 43, for being received in the box 31, is located on the rotating member 40. In one embodiment, the receiving portion 43 is defined by three panels which extend from three edges of the opening 41. Two pivoting portions 44, each with a second pivoting hole 441, are located on opposite sides of the receiving portion 43. A rotating post 50 can be received in the first and second pivoting holes 315, 441. A cutout 51, corresponding to the engaging portion 310, is defined in the rotating post 50. In one embodiment, a diameter of a distal end of the rotating post 50 is greater than that of the first pivoting hole 315. A shielding portion 45 extends from an edge of opening 41, for covering the rotating post 50. In one embodiment, the shielding portion 45 is substantially arcuate. Two blocking portions 46 and a second hook 47 are located on the rotating member 40. The second hook 47 is located between the two blocking portions 46. In one embodiment, a cross-section of the blocking portion 46 is substantially a trapezoid. A resilient member 60 can be secured to the first and second hooks 313, 47. In one embodiment, the resilient member 60 is an extension spring.

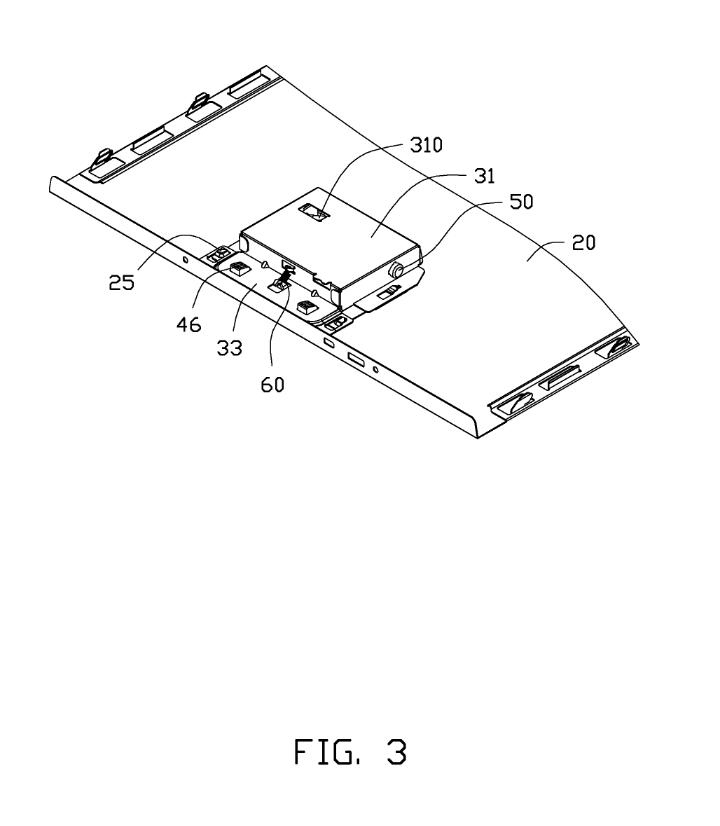

FIG. 3 illustrates the assembly of the side plate 20, the securing member 30, and the rotating member 40 of FIG. 2 in accordance with an embodiment. In assembly, the securing member 30 is aligned with the hole 23, and the plurality of inserting portions 25 are inserted into the plurality of large portions 3514. The securing member 30 is slid, to engage the plurality of inserting portions 25 in the plurality of small portions 3512. Thus, the securing member 30 is secured to the side plate 20. The rotating member 40 is aligned with the securing member 30, and the receiving portion 43 is received in the box 31. The first pivoting hole 315 is aligned with the second pivoting hole 441. The rotating post 50 is engaged in the first pivoting hole 315 and the second pivoting hole 441, to secure the rotating post 50 to the securing member 30 and the rotating member 40. At this point, the engaging portion 310 is engaged in the cutout 51, to prevent the rotating post 50 disengaging from the first pivoting hole 315 and the second pivoting hole 441. The shielding portion 45 covers the rotating post 50, to prevent the rotating post 50 from being exposed. The second hook 47 extends through the first through hole 331, and the two blocking portions 46 extend through the two second through holes 333. A first end of the resilient member 60 is clipped with the first hook 313, and a second end of the resilient member 60 is clipped with the second hook 47. Thereby, the resilient member 60 is secured to the securing member 30 and the rotating member 40.

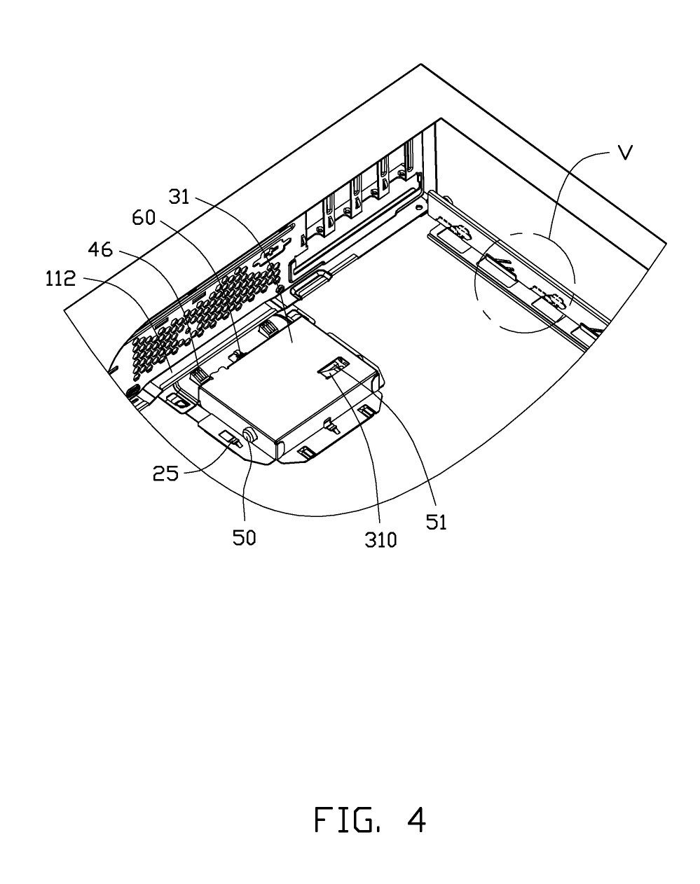

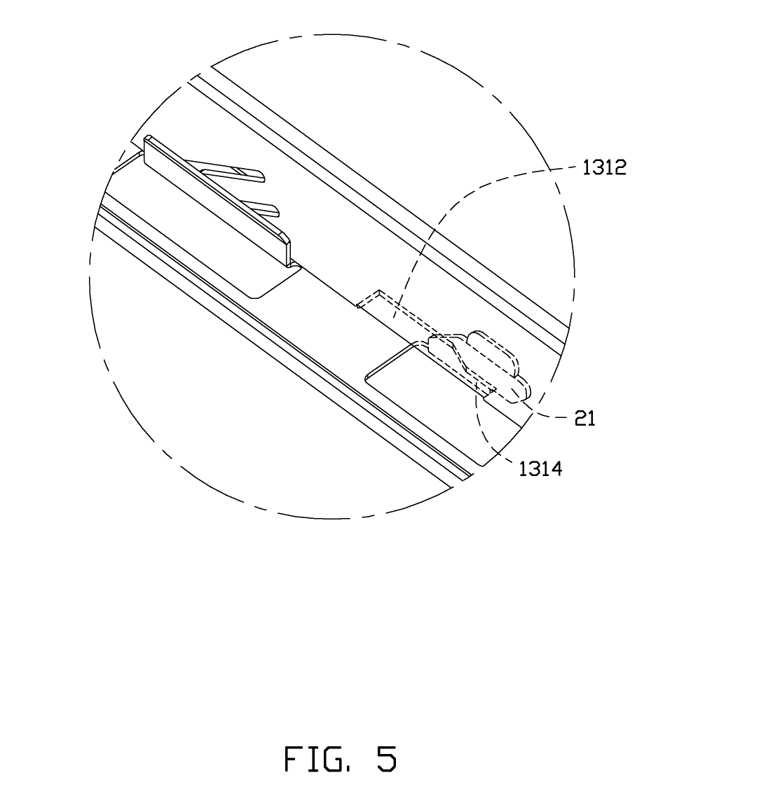

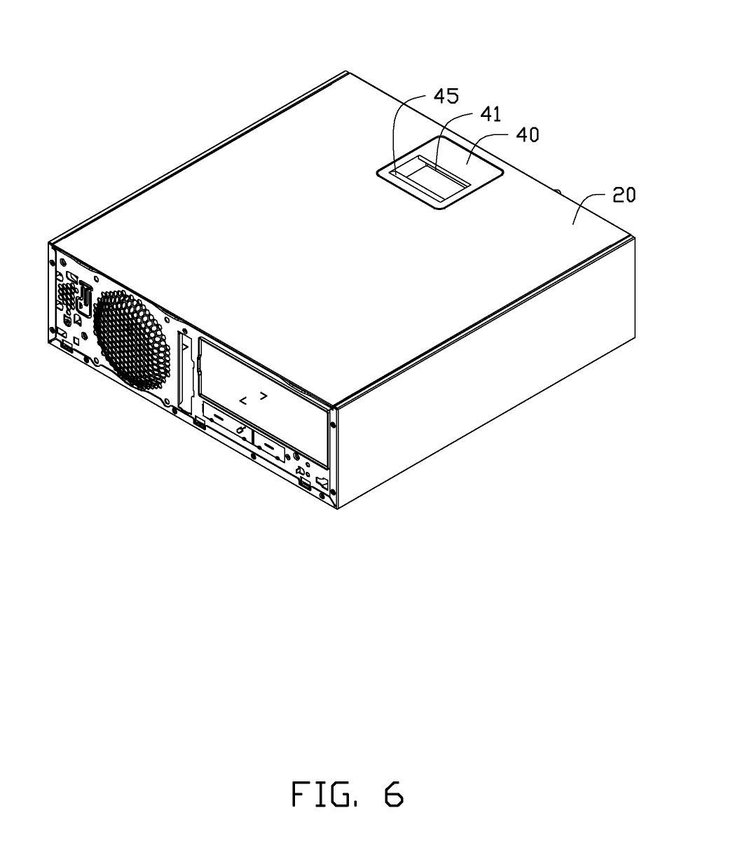

FIGS. 4-6 illustrate the assembly of the electronic device enclosure in accordance with an embodiment. In assembly, the side plate 20 is moved towards the base 10 until the two blocking portions 46 are blocked by the rear wall flange 112. The rotating member 40 is rotated about the rotating post 50 in a direction away from the side plate 20. The resilient member 60 deforms, and the plurality of clamping portions 21 are slid into the plurality of guiding portions 1312. The side plate 20 is moved in a first direction substantially perpendicular to the rear wall 11, and the plurality of clamping portions 21 are each engaged in the plurality of positioning portions 1314. The rotating member 40 is away from the rear wall flange 112 and rotated towards the side plate 20 and the resilient member 60 is released, until the two blocking portions 46 abut the rear wall flange 112. In this way, the blocking portions 46 can prevent the side plate 20 from moving in a second direction that is substantially opposite to the first direction, and the plurality of clamping portions 21 cannot be disengaged from the plurality of clipping holes 1310.

In disassembly, the rotating member 40 is moved about the rotating post 50 in the direction away from the side plate 20, and the resilient member 60 deforms. The two blocking portions 46 disengage from rear wall flange 112 and exit out of the two second through holes 333. The side plate 20 is moved in a second direction, and the plurality of clamping portions 21 are slid into the plurality of guiding portions 1312. The side plate 20 is moved upward, and the side plate 20 can thus be disengaged from the base 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device enclosure comprising:
a base comprising a rear wall and a sidewall connected to the rear wall; the rear wall comprises a rear wall flange and a clipping hole defined in the sidewall;
a side plate attached to the base and comprising a clamping portion; and
a rotating member rotatably attached to the side plate; the rotating member comprises a blocking portion;
wherein the side plate is moveable in a first direction, substantially perpendicular to the rear wall, to engage the clamping portion in the clipping hole, and the blocking portion engaged with the rear wall flange to prevent the side plate in a second direction that is substantially opposite to the first direction.

2. The electronic device enclosure of claim 1, further comprising a securing member attached to the side plate and a rotating shaft; the rotating member is rotatably secured to the securing member by the rotating shaft and the rotating member is rotatable about the rotating shaft to disengage the blocking portion from the rear wall flange.

3. The electronic device enclosure of claim 2, further comprising a resilient member, wherein a first end of the resilient member is engaged with the securing member, and a second end of the resilient member is engaged with the rotating member.

4. The electronic device enclosure of claim 2, wherein the rotating shaft comprises a cutout, and the securing member comprises an abutting portion, engaged in the cutout.

5. The electronic device enclosure of claim 2, wherein the securing member defines a through hole, and the blocking portion extends through the through hole and abuts the rear wall flange.

6. The electronic device enclosure of claim 2, wherein the securing member defines a sliding slot, the side plate comprises an inserting portion, and the inserting portion is slidably engaged in the sliding slot.

7. The electronic device enclosure of claim 2, wherein the rotating member defines an opening; a shielding portion extends from the opening, and the shielding portion covers the rotating shaft.

8. The electronic device enclosure of claim 7, wherein the shielding portion is substantially arcuate.

9. The electronic device enclosure of claim 1, wherein a cross-section of the blocking portion is substantially a trapezoid.

10. The electronic device enclosure of claim 1, wherein the clipping hole comprises a guiding portion and a positioning portion communicating with the guiding portion, and the clamping portion extends through the guiding portion and engaged in the positioning portion.

11. An electronic device enclosure comprising:
a base comprising a rear wall and a sidewall connected to the rear wall; the rear wall comprises a rear wall flange and a clipping hole defined in the sidewall;
a side plate attached to the base and comprising a clamping portion slidably received in the clipping hole;
a securing member slidably attached to the side plate; and
a rotating member rotatably attached to the securing member; the rotating member comprises a blocking portion engaged with the rear wall flange;
wherein the rotating member is rotatable relative to the securing member to disengage the blocking portion from the rear wall flange, and the side plate is moveable in a direction substantially perpendicular to the rear wall to disengage the clamping portion from the clipping hole.

12. The electronic device enclosure of claim 11, further comprising a resilient member, wherein a first end of the resilient member is engaged with the securing member, and a second end of the resilient member is engaged with the rotating member.

13. The electronic device enclosure of claim 11, further comprising a rotating shaft configured for rotatably securing the rotating member to the securing member, the rotating shaft comprises a cutout, and the securing member comprises an abutting portion engaged in the cutout.

14. The electronic device enclosure of claim 13, wherein the rotating member defines an opening; a shielding portion extends from the opening, and the shielding portion covers the rotating shaft.

15. The electronic device enclosure of claim 14, wherein the shielding portion is substantially arcuate.

16. The electronic device enclosure of claim 14, wherein the securing member comprises a box, the abutting portion is located on the bottom of the box, and a receiving portion extends from three edges of the opening and received in the box.

17. The electronic device enclosure of claim 11, wherein the securing member defines a through hole, and the blocking portion extends through the through hole and abuts the rear wall flange.

18. The electronic device enclosure of claim 11, wherein the securing member defines a sliding slot, the side plate comprises an inserting portion, and the inserting portion is slidably engaged in the sliding slot.

19. The electronic device enclosure of claim 11, wherein a cross-section of the blocking portion is substantially a trapezoid.

20. The electronic device enclosure of claim 11, wherein the clipping hole comprises a guiding portion and a positioning portion communicating with the guiding portion, and the clamping portion extends through the guiding portion and engaged in the positioning portion.
